(19) United States
(12) Patent Application Publication
(10) Pub. No.: US 2009/0166757 A1
(43) Pub. Date: Jul. 2, 2009

(54) STRESS ENGINEERING FOR SRAM STABILITY

(75) Inventors: Christopher V. Baiocco, Newburgh, NY (US); Xiandong Chen, Poughquag, NY (US); Young G. Ko, Fishkill, NY (US); Melanie J. Sherony, Fishkill, NY (US)

Correspondence Address: SCULLY, SCOTT, MURPHY & PRESSER, P.C., 400 GARDEN CITY PLAZA, Suite 300, GARDEN CITY, NY, 11530, US

(73) Assignees: INTERNATIONAL BUSINESS MACHINES CORPORATION, Armonk, NY (US); SAMSUNG ELECTRONICS CO., LTD., Gyeonggi-Do (KR)

(21) Appl. No.: 11/964,879

(22) Filed: Dec. 27, 2007

(51) Int. Cl. G06F 17/50; H01L 27/11

(52) U.S. Cl. 257/393; 716/5; 257/E27.099

(57) ABSTRACT

A design structure embodied in a machine readable medium is provided for use in the design, manufacturing, and/or testing of Ics that include at least one SRAM cell. In particular, the present invention provides a design structure of an IC embodied in a machine readable medium, the IC including at least one SRAM cell with a gamma ratio of about 1 or greater. In the present invention, the gamma ratio is increased with degraded pFET device performance. Moreover, in the inventive IC, there is no stress liner boundary present in the SRAM region and ion variation for all devices is reduced as compared to that of a conventional SRAM structure. The present invention provides a design structure of an IC embodied in a machine readable medium, the IC comprising at least one static random access memory cell including at least one nFET and at least one pFET; and a continuous relaxed stressed liner located above and adjoining the at least one nFET and the at least one pFET.

### RELATED APPLICATIONS

This application is related to co-pending and co-assigned U.S. patent application Ser. No. 11/611,569, filed Dec. 15, 2006, currently pending.

### FIELD OF THE INVENTION

The present invention relates to an integrated circuit (IC) and more particularly, to a design structure embodied in a machine readable medium for use in the design, manufacturing, and/or testing of ICs.

### BACKGROUND OF THE INVENTION

The shrinking of metal oxide semiconductor field effect transistor (MOSFET) dimensions for high density, low power and enhanced performance requires reduced power supply voltages. As a result, dielectric thickness and channel length of the transistors are scaled with power supply voltage.

A static random access memory (SRAM) is a significant memory device due to its high speed, low power consumption, and simple operation. Unlike a dynamic random access memory (DRAM) cell, the SRAM does not need to regularly refresh the stored data and it has a straightforward design. However, SRAM stability is severely impacted by scaling. Small mismatches in the devices during processing can cause the cell to favor one of the states, either a ‘1’ or a ‘0’. Mismatches can result from dislocations between the drain and the source or from dopant implantation or thermal anneal temperature fluctuation.

The SRAM cell stability determines the soft-error and the sensitivity of the memory cell to variations in process and operating conditions. One important parameter for the stability is called “gamma ratio”, which is the ratio between the pass-gate nFET ion current and the pull-up pFET ion current.

Stress engineering has been used to improve device performance of FET devices. In particular, stressed liners have been used in recent technologies to improve the device performance. A stressed liner can improve only one type (n-type or p-type) of device, while degrading performance of the other type of device. For example, tensile stress liners are employed for n-type FET device performance improvement, yet the same degrades the device performance of p-type FETs. Similarly, compressive stress liners are employed for p-type FETs device performance improvement, yet the same degrades the device performance of n-type FETs.

Dual stress liner technology in which both compressive and tensile stress liners are present or a relaxation implantation (usually compressive for pFET and relaxation for nET) have been used in the prior art to avoid the degradation.

Despite the above schemes, the SRAM device stability is degraded because of the following: (i) stress liner uniformity in the SRAM region, and (ii) other process variations such as, for example, contact area size and relaxation boundary variation (or tensile and compressive nitride boundary) which can cause the stain variation in the device and therefore the Ion variation for the devices.

As the SRAM dimensions scale down, enhanced SRAM device performance is required in order to obtain good SRAM stability and writability.

In view of the above, there is a need for obtaining SRAM cells wherein the overall device performance is enhanced such that the SRAM has improved stability and writability.

### SUMMARY OF THE INVENTION

The present invention provides an IC including at least one SRAM cell in which the performance of the SWAM cell is enhanced, yet maintaining good stability and writability. In particular, the present invention provides an IC including at least one SRAM cell wherein the gamma ratio is about 1.0 or greater. In the present invention, the gamma ratio is increased with degraded pFET device performance. Moreover, in the inventive IC there is no stress liner boundary present in the SRAM region and ion variation for all devices is reduced as compared to that of a conventional SRAM structure.

It is noted that for a conventional SWAM cell, the pass-gate transistors and the pull-down transistors typically include a compressive and relaxed nitride stress liner, while the pull-up transistors typically include a non-relaxed compressive stressed liner. Alternatively, the pass-gate transistors and the pull-down transistors may include a tensile stress liner. Such a SRAM cell suffers from stability issues, as discussed above.

The present invention solves the above by providing an integrated circuit (IC) that comprises:

at least one static random access memory cell including at least one nFET and at least one pFET; and

a continuous relaxed stressed liner located above and adjoining the at least one nFET and the at least one pFET.

It is noted that in the inventive IC, all transistors, including pass-gate, pull-up and pull-down, within the SRAM cell include a continuous relaxed stressed liner that is located above and adjoining each type of transistor.

Typically, the relaxed stressed liner is a compressive stressed material. More typically, the stressed material is a compressive silicon nitride. The relaxed stressed liner of the present invention includes one of Xe ions and Ge atoms.

The integrated circuit also includes a logic device area (or region) adjacent to an area (or region) including the at least one static random access memory cell wherein the logic device area includes at least one nFET, and at least one pFET. In this embodiment, the relaxed stressed liner is located above and adjoining the at least one nFET of said logic device area and a non-relaxed stressed portion of the liner is located above and adjoining the at least one pFET of the logic device area.

It is emphasized that the stressed liner is a continuous stress liner that has portions that are relaxed and portions that are non-relaxed.

In another embodiment, an integrated circuit (IC) is also provided that includes:

a first area containing at least one SRAM cell, wherein said at least one SRAM cell includes at least one nFET and at least one pFET;

a second area containing at least one logic nFET and at least one logic pFET; and

a continuous stressed liner located above and adjoining each FET, wherein a first portion of said continuous stressed liner located in said second area above and adjoining said at least one logic nFET is relaxed, a second portion of said continuous stressed liner located in said second area above and adjoining said at least one logic pFET is non-relaxed, and a third portion of said continuous stressed liner located in said second area above and adjoining said at least one nFET and said at least one pFET is relaxed.

It is again noted that in the inventive IC, all transistors, including pass-gate, pull-up and pull-down, within the SRAM cell include a continuous relaxed stressed liner that is located above and adjoining each type of transistor.

In another aspect of the invention, a design structure embodied in a machine readable median is also provided that includes:

at least one static random access memory cell including at least one nFET and at least one pFET; and

a continuous relaxed stressed liner located above and adjoining said at least one nFET and at least one pFET, wherein said continuous relaxed stressed liner is a compressive stressed material.

In another aspect of the invention, a design structure embodied in a machine readable medium is also provided that includes:

a first area containing at least one SRAM cell, wherein said at least one SRAM cell includes at least one nFET and at least one pFET;

a second area containing at least one logic nFET and at least one logic pFET; and

a continuous stressed liner located above and adjoining each FET, wherein a first portion of said continuous stressed liner located in said second area above and adjoining said at least one logic nFET is relaxed, a second portion of said continuous stressed liner located in said second area above and adjoining said at least one logic pFET is non-relaxed, and a third portion of said continuous stressed liner located in said first above and adjoining said at least one nFET and said at least one pFET is relaxed, and wherein said continuous stressed liner is a compressive stressed material comprising silicon nitride.

### BRIEF DESCRIPTION OF THE DRAWINGS

FIGS. 1A-1C are pictorial representations (through cross sectional views) depicting the basic process steps employed in the present invention in fabricating an IC including a high performance SRAM that has improved stability and writability.

FIG. 2 is a flow diagram of a design process used in semiconductor design, manufacturing and/or testing.

### DETAILED DESCRIPTION OF THE INVENTION

The present invention, which provides a technique to increase the performance of a SRAM cell while also improving the stability and writability of the SRAM cell as well as the resultant IC that is fabricated utilizing the same, will now be described in greater detail by referring to the following discussion and drawings that accompany the present application. The drawings of the present application are provided for illustrative purposes and, as such, they are not drawn to scale.

In the following description, numerous specific details are set forth, such as particular structures, components, materials, dimensions, processing steps and techniques, in order to provide a thorough understanding of the present invention. However, it will be appreciated by one of ordinary skill in the art that the invention may be practiced without these specific details. In other instances, well-known structures or processing steps have not been described in detail in order to avoid obscuring the invention.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present.

As stated above, the present invention provides an IC including at least one SRAM cell in which the performance of the SRAM cell is enhanced, yet maintaining good stability and writability. In particular, the present invention provides an IC including at least one SRAM cell wherein the gamma ratio is about 1 or greater. In the present invention, the gamma ratio is increased with degraded pFET device performance. Moreover, in the inventive IC there is no stress liner boundary present in the SRAM region and ion variation for all devices is reduced as compared to that of a conventional SRAM structure.

The present invention solves the above by providing an integrated circuit (IC) that comprises at least one static random access memory cell including at least one nFET and at least one pFET; and a continuous relaxed stressed liner located above and adjoining the at least one nFET, and the at least one pFET.

It is noted that in the inventive IC, all transistors, including pass-gate, pull-up and pull-down, within the SRAM cell include a continuous relaxed stressed liner that is located above and adjoining each type of transistor.

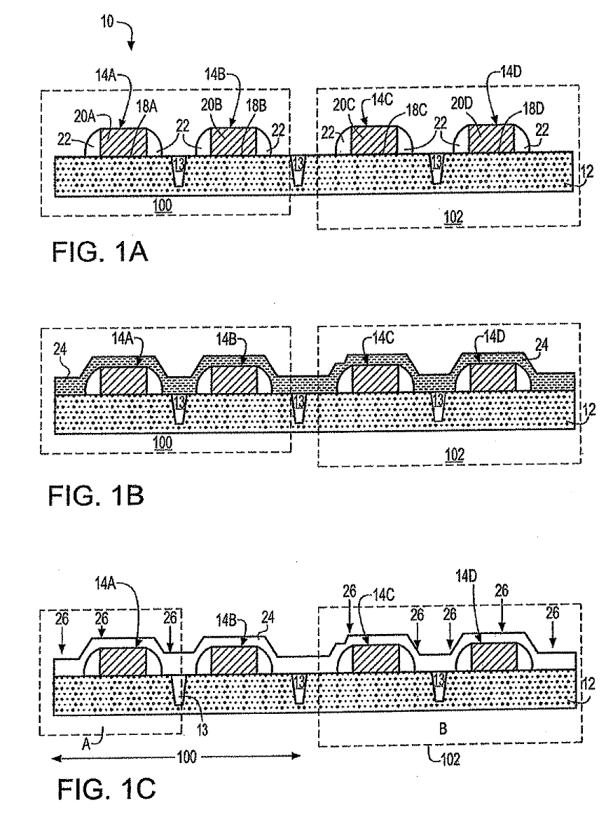

The technique employed in the present invention for providing an IC including a high performance SRAM that has improved stability and writability will now be described in greater detail by referring to FIGS. 1A-1C. Specifically, FIG. 1A illustrates an initial IC 10 that can be employed in the present invention. As shown, the IC 10 includes a semiconductor substrate 12 having trench isolation regions 13 therein. The semiconductor substrate 12 includes at least one logic device region 100 and at least one SRAM device region 102. Although such regions are shown, the present invention works equally well with other types of device regions.

Each of the various device regions (i.e., regions or areas 100 and 102) includes transistors 14A, 14B, 14C and 14D. In the embodiment illustrated, the transistor 14A represents an nFET, the transistor 14B represents a pFET, the transition 14C represents an nFET of the SRAM cell and transistor 14D represents a pFET of the SRAM cell. Transistors 14C and 14D may comprise a pass-gate transistor, a pull-up transistor or a pull-down transistor of a typical SRAM. Although the drawings depict the presence of one of each of the aforementioned types of transistors, a plurality of such transistors can be located on the surface of the semiconductor substrate 12.

It is noted that in the SRAM device region 102, at least one SRAM cell is present that typically includes six transistors, two pass-gate, two pull-down and two pull-up. The SRAM cell layout that is employed in the present invention includes any conventional layout, including for example, the SRAM layout shown in FIG. 4 of U.S. Pat. No. 6,984,564.

Each transistor shown includes a gate stack that comprises at least a gate dielectric 18A, 18B, 18C, and 18D, and a gate conductor 20A, 20B, 20C and 20D. Also present on the sidewalls of each of the gate stacks is a dielectric spacer 22.

The various elements/components shown in FIG. 1A are comprised of materials that are well known to those skilled in the art. For example, the semiconductor substrate 12 includes any semiconductor material including, for example, Si, SiGe, SiGeC, SiC, Ge alloys, GaAs, InAs, InP and other III/V or II/VI compound semiconductors. The semiconductor substrate 12 may be a bulk substrate, a layered substrate (such as Si/SiGe or a semiconductor-on-insulator (SOI)) or a hybrid substrate that has surface regions of different crystallographic orientation. A preferred semiconductor material for substrate 12 is a Si-containing semiconductor.

The substrate 12 may be strained, unstrained or contain regions of strain and unstrain therein. The substrate 12 may also be undoped, doped or contain doped regions and undoped regions.

The trench isolation regions 13 are typically comprised of a trench dielectric material such as a trench oxide and are formed utilizing a conventional trench isolation process. The trench isolation region 13 can be replace with field oxide isolation regions or any other type of isolation region used in the art for separating devices from each other.

The transistors can be formed by deposition, lithography, etching or a replacement gate process can be used. The gate dielectric of each transistor may be the same or different insulating material including, for example, oxides, nitrides, oxynitrides and multilayer stacks of any of these insulators. Preferably, an oxide such as, but not limited to, silicon dioxide is used as the gate dielectric. The gate conductor of each transistor comprises any conductive material including doped polySi, doped SiGe, an elemental metal, an alloy of an elemental metal, a metal silicide or any multilayered stack thereof (e.g., a stack of a metal silicide located atop a polySi base). Preferably, polySi gate conductors are employed. The dielectric spacer of each transistor includes an oxide, nitride, oxynitride and multilayers stacks thereof. Preferably, the spacer is an oxide or nitride of silicon.

It will be appreciated by one skilled in the art that during the manufacturing of each transistor dopants can be introduced into the substrate to form source/drain extension regions, halo implant regions, and source/drain diffusion regions within the substrate at the footprint of each of the transistors. Conventional ion implantations processes can be used in forming any of the above-mentioned regions.

As one skilled in the art is also aware the region of the substrate 12 beneath the gate stack of each transistor is the channel of each device. The channel region is typically laterally confined by the implant regions formed above.

FIG. 1B illustrates the IC structure that is formed after forming a liner 24 on all the exposed surfaces of the structure shown in FIG. 1A. The liner 24 employed in the present invention is a compressive stressed material. The liner 24 may comprise an insulating material such as silicon nitride, a conductive material and/or a semiconductive material. Preferably, silicon nitride is used as the liner 24.

The liner 24 is formed utilizing any conventional deposition process including, for example, a plasma enhanced chemical vapor deposition (PECVD) process as is disclosed in U.S. Patent Application Publication No. 2003/0040158 or a high-density plasma (HPD) deposition. The thickness of the liner 24 may vary and it is not critical to the practice of the present invention.

FIG. 1C illustrates the structure during a relaxation step in which ions 26 that are capable of relaxing the liner 24 are selectively implanted into the liner 24 at regions A and B. Region A denotes a region including only the nFET 14A in logic device region 100, while Region B denotes a region including both the nFETs 14C and the pFETs 14D in the SRAM device region 102. The implanted ions 26 comprise at least one of Xe and Ge. The implantation conditions are selected such that the ions 26 are introduced only to the liner 26. Typical ion implantation conditions include: an ion dosage from about 5E14 to about 2E15 atoms/cm² and an implant energy from about 30 to about 70 keV. The implantation temperature may be nominal room temperature (about 20° C. to about 40° C.).

In FIG. 1C, reference numeral 26′ the relaxed stress liner, while reference numeral 26 denotes a non-relaxed stress liner.

Following the above processing conventional steps can be performed on the structure shown in FIG. 1C.

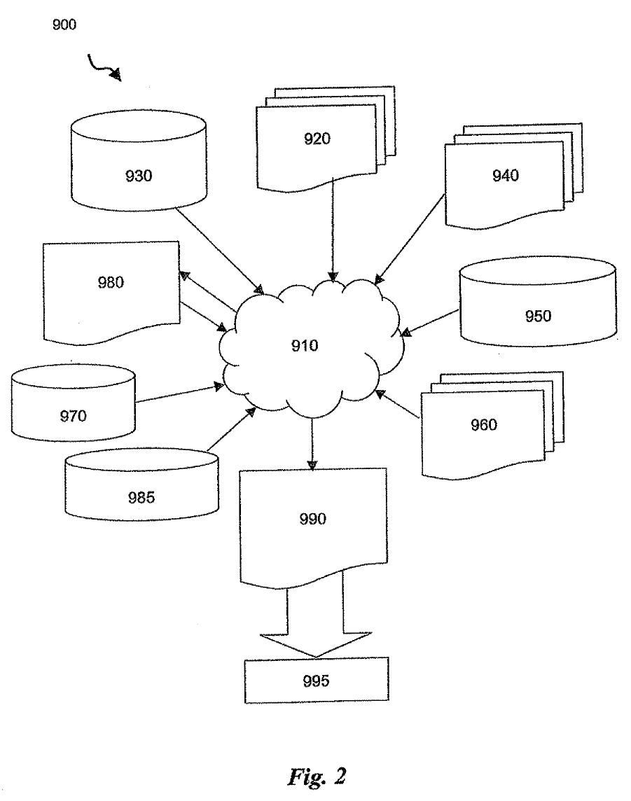

FIG. 2 shows a block diagram of an example design flow 900. Design flow 900 may vary depending on the type of IC being designed. For example, a design flow 900 for building an application specific IC (ASIC) may differ from a design flow 900 for designating a standard component. Design structure 920 is preferably an input to a design process 910 and may come from an IP provider, core developer, or other design company, or may be generated by the operator of the design flow, or from other sources. Design structure 920 comprises the IC illustrated in FIG. 1C in the form of schematics or HDL, a hardware-description language (e.g., Verilog, VHDL, C, etc.). Design structure 920 may be a text file or a graphical representation of the IC shown in FIG. 1C. Design process 910 preferably synthesizes (or translates) the inventive IC shown in FIG. 1C into a netlist 980, where netlist 980 is, for example, a list of wires, transistors, logic gates, control circuits, I/O, models, etc. that describes the connections to other elements and circuits in an integrated circuit design and recorded on at least one of machine readable medium. This may be an iterative process in which netlist 980 is resynthesized one or more times depending on design specifications and parameters for the circuit.

Design process 910 may include using a variety of inputs; for example, inputs from library elements 930 which may house a set of commonly used elements, circuits, and devices, including models, layouts, and symbolic representations for a given manufacturing technology (e.g., different technology nodes, 32 nm, 45 nm, 90 nm, etc.), design specifications 940, characterization data 950, verification data 960, design specifications 970, and test data files 985 (which may include test patterns and other testing information). Design process 910 may further include, for example, standard circuit design processes such as timing analysis, verification, design rule checking, place and route operations, etc. One of ordinary skill in the art of IC design can appreciate the extent of possible electronic design automation tools and applications used in design process 910 without deviating from the scope and spirit of the invention. The design structure of the invention is not limited to any specific design flow.

Design process 910 preferably translates an embodiment of the invention as shown in FIG. 1C, along with any additional integrated circuit design or data into a second design structure 990. Design structure 990 resides on a storage medium in a data format used for the exchange of layout data of integrated circuits (e.g., information stored in a GDSII (GDS2), GL1, OASIS, or any other suitable format for storing such design structures). Design structure 990 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as shown in FIG. 1. Design structure 990 may then proceed to a stage 995 where, for example, design structure 990: proceeds to tape-out, is released to manufacturing, is released to a mask house, is sent to another design house, is sent back to the customer, etc.

While the invention has been described herein with reference to specific embodiments, features and aspects, it will be recognized that the invention is not thus limited, but rather extends in utility to other modifications, variations, applications, and embodiments, and accordingly all such other modifications, variations, applications, and embodiments are to be regarded as being within the spirit and scope of the invention.

What is claimed is:

1. A design structure embodied in a machine readable medium, the design structure comprising:
at least one static random access memory cell including at least one nFET and at least one pFET; and
a continuous relaxed stressed liner located above and adjoining said at least one nFET and at least one pFET, wherein said continuous relaxed stressed liner is a compressive stressed material.

2. The design structure of claim 1, further comprising a logic device area adjacent to an area including said at least one static random access memory cell, wherein said logic device area includes at least one nFET, at least one pFET, the continuous relaxed stressed liner located above and adjoining said at least one nFET of said logic device area and a non-relaxed stressed portion of said liner located above and adjoining said at least one pFET of said logic device area, and wherein said relaxed stressed liner and said non-relaxed stressed portion of said liner comprise a continuous compressively stressed material.

3. The design structure of claim 1, wherein the design structure comprises:
a netlist which describes an integrated circuit (IC); and
at least one of test data files, characterization data, verification data, or design specifications.

4. The design structure of claim 3, wherein the design structure resides on a storage medium as a data format used for the exchange of layout data of the IC.

5. A design structure embodied in a machine readable medium, the design structure comprising:
a first area containing at least one SRAM cell, wherein said at least one SRAM cell includes at least one nFET and at least one pFET;
a second area containing at least one logic nFET and at least one logic pFET; and
a continuous stressed liner located above and adjoining each FET, wherein a first portion of said continuous stressed liner located in said second area above and adjoining said at least one logic nFET is relaxed, a second portion of said continuous stressed liner located in said second area above and adjoining said at least one logic pFET is non-relaxed, and a third portion of said continuous stressed liner located in said first above and adjoining said at least one nFET and said at least one pFET is relaxed, and wherein said continuous stressed liner is a compressive stressed material comprising silicon nitride.

6. The design structure of claim 5, wherein the design structure comprises:
a netlist which describes an integrated circuit (IC); and
at least one of test data files, characterization data, verification data, or design specifications.

7. The design structure of claim 6, wherein the design structure resides on a storage medium as a data format used for the exchange of layout data of the IC.
